(19) United States
(12) Patent Application Publication
(10) Pub. No.: US 2003/0085455 A1
(43) Pub. Date: May 8, 2003

(54) Thermal ring used in 3-D stacking

(76) Inventors: Glen E. Roeters, Huntington Beach, CA (US); Frank E. Mantz, Hawthorne, CA (US)

Correspondence Address: STETINA BRUNDA GARRED & BRUCKER, 75 ENTERPRISE, SUITE 250, ALISO VIEJO, CA, 92656, US

(21) Appl. No.: 09/994,002

(22) Filed: Nov. 6, 2001

(51) Int. Cl. H01L 23/02

(52) U.S. Cl. 257/686

(57) ABSTRACT

A chip stack comprising at least two carrier layers, each of which includes a first conductive pattern disposed thereon. The chip stack further comprises at least one thermal ring having a second conductive pattern disposed thereon. The thermal ring is formed to include at least two flow channels. The thermal ring is disposed between the carrier layers, with the second conductive pattern being electrically connected to the first conductive pattern of each of the carrier layers. Also included in the chip stack are at least two integrated circuit chips which are electrically connected to respective ones of the first conductive patterns. One of the integrated circuit chips is circumvented by the thermal ring and disposed between the carrier layers. The flow channels within the thermal ring facilitate the circulation of cooling air over the integrated circuit chip disposed between the carrier layers.

### CROSS-REFERENCE TO RELATED APPLICATIONS

(Not Applicable)

### STATEMENT RE: FEDERALLY SPONSORED RESEARCH/DEVELOPMENT

(Not Applicable)

### BACKGROUND OF THE INVENTION

The present invention relates generally to a heat dissipation structure for integrated circuit (IC) chip stacks, and more particularly to a thermal ring interposed in a 3-D chip stack.

As is currently known in the art, packaged components are often stacked using a variety of approaches. In all of the approaches to date, the concept has been to mount the stacks on the surface of a solid board such as a printed circuit board (PCB). More particularly, one of the most commonly used techniques to increase memory capacity is the stacking of memory devices into a vertical chip stack, sometimes referred to as 3D packaging or Z-Stacking. In the Z-Stacking process, from two to as many as eight memory devices or other integrated circuit (IC) chips are interconnected in a single component (i.e., a chip stack) which is mountable to the “footprint” typically used for a single packaged device such as a packaged chip. The Z-Stacking process has been found to be volumetrically efficient, with packaged chips in TSOP (thin small outline package) or LCC (leadless chip carrier) form generally being considered to be the easiest to use. Some have used bare dies in the Z-Stacking process, however, such use tends to make the stacking process more complex and not well suited to automation.

As the components are stacked inside of the 3-D stack, it is difficult to obtain an effective and direct path for dissipating the heat generated thereby. This situation is more problematic for the 3-D stack incorporating high power electronic components with high heat dissipation ratings. Hence, there is an urgent need for thermal management to efficiently remove the heat from the 3-D stacks. The thermal performance of 3-D stacks is further challenging with the development of high-performance components, smaller packages and lower silicon operating temperatures.

### BRIEF SUMMARY OF THE INVENTION

In accordance with the present invention, there is provided a chip stack comprising at least two carrier layers (i.e., an upper carrier layer and a lower carrier layer). Each of the carrier layers includes a first conductive pattern disposed thereon. The chip stack further comprises at least one thermal ring having a second conductive pattern disposed thereon. The thermal ring is disposed between the upper and lower carrier layers, with the second conductive pattern being electrically connected to the first conductive pattern of each of the carrier layers. In addition to the carrier layers and thermal ring, the chip stack comprises at least two integrated circuit chips which are electrically connected to respective ones of the first conductive patterns. The integrated circuit chip electrically connected to the first conductive pattern of the lower carrier layer is at least partially circumvented by the thermal ring and at least partially covered by the upper carrier layer. The chip stack may further comprise a transposer layer having a third conductive pattern disposed thereon. If the transposer layer is included in the chip stack, the first conductive pattern of the lower carrier layer is electrically connected to the third conductive pattern of the transposer layer.

In the present chip stack, the thermal ring is formed to define a plurality of castellations. Defined between each adjacent pair of the castellations is a flow channel. The flow channels are operative to facilitate the circulation of air over the integrated circuit chip which is circumvented by the thermal ring and disposed between the carrier layers. To further assist in the heat dissipation function, a heat sink may be attached to the integrated circuit chip disposed between the carrier layers. Within each castellation of the thermal ring is one or more vias or feed-through holes which form a Z-axis interconnect. Once the thermal ring has been placed about the integrated circuit chip and between the carrier layers, the Z-axis connection is made from the thermal ring to the carrier layers. As indicated above, once the chip stack has been completely assembled, air is free to flow through the flow channels defined between the castellations in the thermal ring to cool the component(s) and the chip stack itself. The transposer layer of the chip stack translates the chip stack to route the I/O's of the integrated circuit devices to the appropriate pattern. The stacking approach of the present invention enables the stacking of the integrated circuit devices, one on top of the other, with vertical as well as horizontal interconnections. The configuration of the thermal ring addresses the thermal challenge of three-dimensional stacks by providing the cooling function described above.

### BRIEF DESCRIPTION OF THE DRAWINGS

These as well as other features of the present invention will become more apparent upon reference to the drawings wherein:

FIG. 1 is a top perspective view of a chip stack including a thermal ring constructed in accordance with the present invention;

FIG. 2 is an exploded view of the chip stack shown in FIG. 1; and

FIG. 3 is a top perspective view of the thermal ring shown in FIGS. 1 and 2.

### DETAILED DESCRIPTION OF THE INVENTION

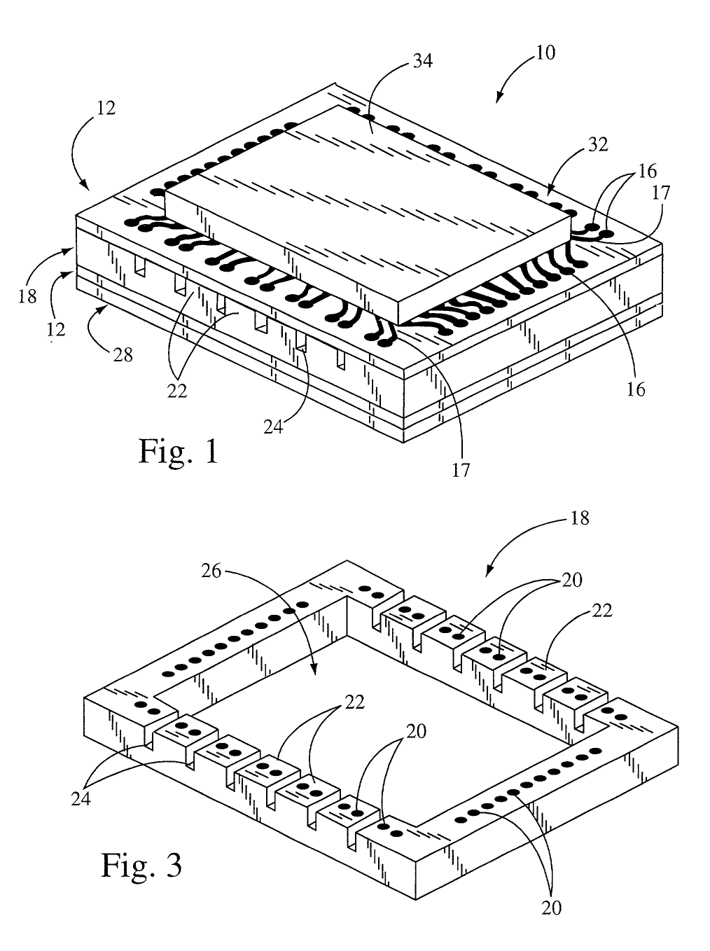

Referring now to the drawings wherein the showings are for purposes of illustrating a preferred embodiment of the present invention only, and not for purposes of limiting the same, FIG. 1 perspectively illustrates a chip stack 10 constructed in accordance with the present invention. The chip stack 10 comprises at least two identically configured component carrier layers 12. Each of the component carrier layers 12 is rectangularly configured and defines opposed, generally planar top and bottom surfaces, an opposed pair of longitudinal peripheral edge segments, and an opposed pair of lateral peripheral edge segments.

Disposed on each component carrier layer 12 is a first conductive pad array which itself preferably comprises a first set of carrier pads 14 and a second set of carrier pads 16. The carrier pads 14 of the first set are preferably arranged in a generally rectangular pattern or array in the central portion of the top surface of each carrier layer 12. The carrier pads 16 of the second set are preferably arranged so as to extend linearly along the longitudinal and lateral peripheral edge segments of each carrier layer 12. The carrier pads 14 of the first set are electrically connected to respective ones of the carrier pads 16 of the second set via conductive traces 17.

In addition to the carrier pads 14, 16 of the first and second sets, the first conductive pad array of each carrier layer 12 comprises a third set of carrier pads which are disposed on the bottom surface of the carrier layer 12. The carrier pads of the third set are preferably arranged in an identical pattern to the carrier pads 16 of the second set, and extend linearly along the longitudinal and lateral peripheral edge segments of the carrier layer 12 such that each of the carrier pads of the third set is aligned with and electrically connected to a respective one of the carrier pads 16 of the second set. Such electrical connection is preferably facilitated through the use of a via or feed-through hole.

In addition to the carrier layers 12, the chip stack 10 of the present invention comprises at least one rectangularly configured interposer thermal ring 18. The thermal ring 18 defines opposed top and bottom surfaces, an opposed pair of longitudinal side sections, and an opposed pair of lateral side sections. Disposed on the thermal ring 18 is a second conductive pad array which itself preferably comprises a first set of ring pads 20 disposed on the top surface, and a second set of ring pads disposed on the bottom surface. The ring pads 20 of the first set and ring pads of the second set are preferably arranged in patterns which are identical to each other, and to the patterns of the carrier pads 16 of the second set and carrier pads of the third set of each of the carrier layers 12. In this respect, the ring pads 20 of the first set and ring pads of the second set each extend linearly along the longitudinal and lateral side sections of the thermal ring 18, with each of the ring pads 20 of the first set being aligned with and electrically connected to a respective one of the ring pads of the second set. Similar to the electrical connection of the carrier pads 16 of the second set to the carrier pads of the third set, the electrical connection of each of the ring pads 20 of the first set to a respective one of the ring pads of the second set may be accomplished through the use of a via or feed-through hole.

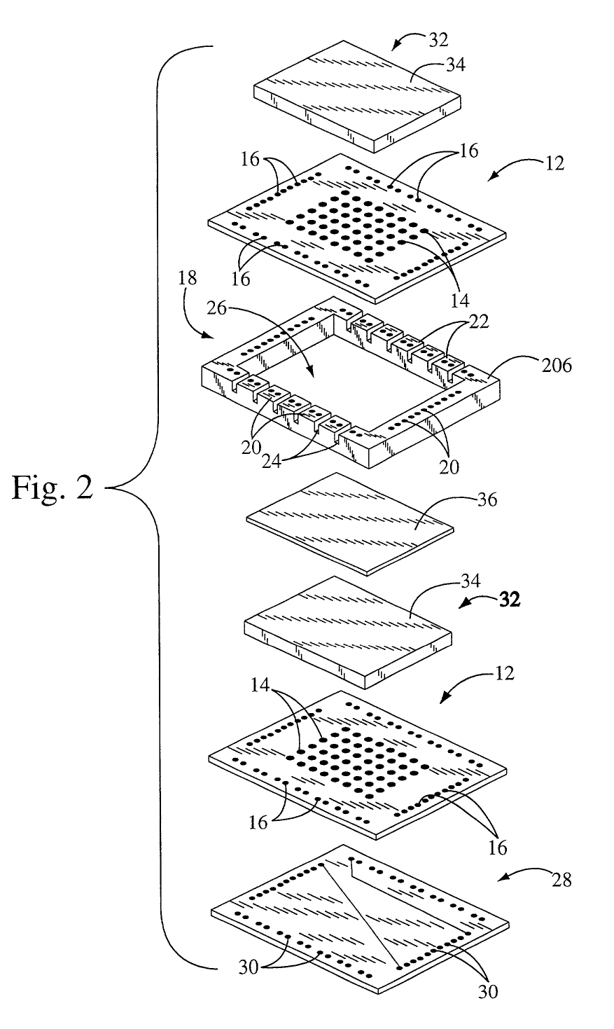

As best seen in FIG. 3, the longitudinal side sections of the thermal ring 18 are each preferably crenellated so as to define a series of castellations 22. Each adjacent pair of castellations 22 is separated by a rectangularly configured flow channel 24, with each of the outermost pair of castellations 22 of each longitudinal side section being separated from the remainder of the thermal ring 18 by a flow channel 24. The castellations 22 and flow channels 24 are formed within each of the longitudinal side sections of the thermal ring 18. The flow channels 24 extend downwardly from the top surface of the thermal ring 18 to a depth equal to approximately half of the total thickness or height thereof. Additionally, as seen in FIGS. 2 and 3, the ring pads 20 of the first set are arranged such that a pair of ring pads 20 are included upon each of the castellations 22.

Those of ordinary skill in the art will recognize that different numbers of castellations 22 and flow channels 24 may be included in each of the longitudinal side sections of the thermal ring 18, and that such castellations 22 and flow channels 24 may be formed in the lateral side sections of the thermal ring 18 as well. Moreover, the depth and cross-sectional configuration of each of the flow channels 24 may be varied. The thermal ring 18 is preferably fabricated from a printed circuit board (PCB) substrate material or other thermally managed material. The vias extending between corresponding pairs of the ring pads 20 of the first set and the ring pads of the second set provide a Z-axis interconnect, as do the vias extending between corresponding pairs of the carrier pads 16 of the second set and carrier pads of the third set in each of the carrier layers 12. As will be discussed in more detail below, the flow channels 24 provide air flow passages from the exterior of the thermal ring 18 into a rectangularly configured opening 26 defined thereby.

In the chip stack 10, the thermal ring 18 is disposed between the carrier layers 12, with the second conductive pattern of the thermal ring 18 being electrically connected to the first conductive pattern of each of the carrier layers 12. More particularly, the ring pads of the second set are electrically connected to respective ones of the carrier pads 16 of the second set of one of the carrier layers 12 (i.e., the carrier layer 12 immediately below the thermal ring 18 in the chip stack 10), with the ring pads 20 of the first set being electrically connected to respective ones of the carrier pads of the third set of one of the carrier layers 12 (i.e., the carrier layer 12 immediately above the thermal ring 18 in the chip stack 10). Due to the carrier pads 16 of the second set, carrier pads of the third set, ring pads 20 of the first set, and ring pads of the second set all being arranged in identical patterns, each coaxially aligned pair of ring pads is itself coaxially aligned with a coaxially aligned set of carrier pads of the second and third sets of each of the adjacent carrier layers 12. The electrical connection of the second conductive pattern of the thermal ring 18 to the first conductive pattern of each of the adjacent carrier layers 12 is preferably facilitated via a soldering process.

Referring now to FIGS. 1 and 2, the chip stack 10 of the present invention may further comprise a rectangularly configured transposer layer 28 which defines opposed, generally planar top and bottom surfaces, an opposed pair of longitudinal peripheral edge segments, and an opposed pair of lateral peripheral edge segments. Disposed on the transposer layer 28 is a third conductive pattern. The third conductive pattern comprises a first set of transposer pads 30 which are disposed on the top surface of the transposer layer 28, and a second set of transposer pads which are disposed on the bottom surface thereof. The transposer pads 30 of the first set are electrically connected to respective ones of the transposer pads of the second set. The transposer pads 30 of the first set are preferably arranged in a pattern which is identical to the patterns of the second set of carrier pads 16, third set of carrier pads, first set of ring pads 20 and second set of ring pads. In this respect, the transposer pads 30 of the first set extend linearly along the longitudinal and lateral peripheral edge segments of the transposer layer 28. The transposer pads of the second set may be arranged in any pattern as required to electrically interface the chip stack 10 to a desired footprint on a printed circuit board or other substrate. The pattern of the transposer pads of the second set may be identical to that of the carrier pads 14 of the first set so as to mimic a BGA pattern.

If the transposer layer 28 is included in the chip stack 10, the first conductive pattern of one of the carrier layers 12 (i.e., the lowermost carrier layer 12 in the chip stack 10) is electrically connected to the third conductive pattern of the transposer layer 28. More particularly, each of the carrier pads of the third set of the lowermost carrier layer 12 is electrically connected to a respective one of the transposer pads 30 of the first set. Due to the carrier pads of the third set and the transposer pads 30 of the first set being arranged in identical patterns, each of the carrier pads of the third set is coaxially alignable with a respective one of the transposer pads 30 of the first set, with the electrical connection therebetween preferably being facilitated via soldering. The transposer layer 28 and carrier layers 12, like the thermal ring 18, are also preferably fabricated from a printed circuit board material or other material having thermal dissipation properties.

As best seen in FIG. 2, the chip stack 10 of the present invention further comprises at least two identically configured integrated circuit chips, and more particularly packaged chips 32, which are electrically connected to respective ones of the first conductive patterns of the carrier layers 12. Each of the packaged chips 32 comprises a rectangularly configured body 34 defining opposed, generally planar top and bottom surfaces, an opposed pair of longitudinal sides, and an opposed pair of lateral sides. Disposed on the bottom surface of the body 34 are a plurality of conductive contacts which are arranged in a pattern identical to that of the carrier pads 14 of the first set of each of the carrier layers 12. The conductive contacts of each of the packaged chips 32 are electrically connected to respective ones of the carrier pads 14 of the first set of a respective one of the first conductive patterns of the carrier layers 12. Due to the conductive contacts of the packaged chips 32 and the carrier pads 14 of each of the first sets being arranged in identical patterns, the conductive contacts of each of the packaged chips 32 are coaxially alignable with respective ones of the carrier pads 14 of the corresponding first set. The electrical connection of the conductive contacts of each packaged chip 32 to respective ones of the carrier pads 14 of the first set of a respective one of the first conductive patterns is preferably accomplished via soldering. Each of the packaged chips 32 may be a BGA (ball grid array) device, also referred to as a CSP (chip scale package), micro-BGA, or a flip chip. As indicated above, each of the packaged chips 32 has solder ball interconnects located in rows and columns on the bottom surface of the body 34.

The complete chip stack 10 shown in FIG. 1 includes the transposer layer 28, two carrier layers 12, one thermal ring 18, and two packaged chips 32. The first conductive pattern of the lowermost carrier layer 12 is connected to the third conductive pattern of the transposer layer 28 in the above-described manner. Additionally, the thermal ring 18 is disposed or positioned between the carrier layers 12, with the second conductive pattern of the thermal ring 18 being electrically connected to the first conductive pattern of each of the carrier layers 12 in the above-described manner. Since the conductive contacts of each of the packaged chips 32 are electrically connected to respective ones of the carrier pads 14 of the first set of respective ones of the first conductive patterns, the lowermost packaged chip 32 within the chip stack 10 is disposed between the carrier layers 12 and circumvented by the thermal ring 18. Thus, such lowermost packaged chip 32 resides within the opening 26 defined by the thermal ring 18, with the body 34 of the packaged chip 32 and thermal ring 18 preferably being sized relative to each other such that the top surface of the body 34 does not protrude beyond the top surface of the thermal ring 18.

As indicated above, the various electrical connections within the chip stack 10 are preferably facilitated through the use of standard solder joints or through the use of alternative interconnect methods. Those of ordinary skill in the art will recognize that the chip stack 10 may be formed to include more than two carrier layers 12, one thermal ring 18, and two packaged chips 32.

In the complete chip stack 10, the structural attributes of the thermal ring 18, and in particular the flow channels 24 formed therein, are used to provide air flow over and about the packaged chip 32 captured between the carrier layers 12 and circumvented by the thermal ring 18, thus effectively cooling the same. As seen in FIG. 2, if the packaged chip 32 comprises an extremely high temperature component, thermal dissipation can be further increased by attaching a heat sink 36 to the top surface of the body 34 of any packaged chip(s) 32 circumvented by the thermal ring(s) 18. The heat sink 36 may be attached to the body 34 through the use of an adhesive, and is preferably fabricated from a thermally conductive material such as copper. As will be recognized, the inclusion of the heat sink 36 within the chip stack 10 allows heat to dissipate through the copper of the heat sink 36 and to be carried away by the air current flowing through the flow channels 24 defined between the castellations 22 within the thermal ring 18.

In forming the chip stack 10, the various layers can be easily stacked using a panel format, with the stacked panels then being separated using standard PCB routing procedures to form the chip stacks 10. For example, typical four inch by six inch panels with multiple stack sites may be processed, then stacked in a conventional stacking fixture. Such panels can easily be designed with multiple devices per layer for each chip stack 10. In this regard, multiple devices such as BGAs, TSOPs (thin small outline packages), or bare dies can be intermixed and placed on one carrier layer 12. Additionally, it is contemplated that the chip stack 10 may be manufactured in a manner wherein the lowermost carrier layer 12 and transposer layer 28 may be combined into a single substrate or layer. As indicated above, though FIGS. 1-3 show the chip stack 10 as a two component stack, additional layers/devices can be assembled in the above-described manner.

Additional modifications and improvements of the present invention may also be apparent to those of ordinary skill in the art. Thus, the particular combination of parts described and illustrated herein is intended to represent only certain embodiments of the present invention, and is not intended to serve as limitations of alternative devices within the spirit and scope of the invention.

1. A chip stack comprising:
at least two carrier layers, each of the carrier layers including a first conductive pattern disposed thereon;
at least one thermal ring having a second conductive pattern disposed thereon and including at least two flow channels disposed therein, the thermal ring being disposed between the carrier layers, with the second conductive pattern being electrically connected to the first conductive pattern of each of the carrier layers; and
at least two integrated circuit chips electrically connected to respective ones of the first conductive patterns, one of the integrated circuit chips being circumvented by the thermal ring and disposed between the carrier layers;
the flow channels being operative to facilitate the circulation of air over the integrated circuit chip disposed between the carrier layers.

2. The chip stack of claim 1 further comprising:
a transposer layer having a third conductive pattern disposed thereon;
the first conductive pattern of one of the carrier layers being electrically connected to the third conductive pattern.

3. The chip stack of claim 2 wherein:
each of the carrier layers defines opposed top and bottom surfaces; and
the first conductive pattern of each of the carrier layers comprises:
a first set of carrier pads disposed on the top surface;
a second set of carrier pads disposed on the top surface and electrically connected to respective ones of the carrier pads of the first set; and
a third set of carrier pads disposed on the bottom surface and electrically connected to respective ones of the carrier pads of the second set;
the integrated circuit chips being disposed upon respective ones of the top surfaces and electrically connected to at least some of the carrier pads of respective ones of the first sets, with the carrier pads of the second set of one of the carrier layers being electrically connected to the second conductive pattern, and the carrier pads of the third set of one of the carrier layers being electrically connected to the second conductive pattern.

4. The chip stack of claim 3 wherein:
the thermal ring defines opposed top and bottom surfaces; and
the second conductive pattern comprises:
a first set of ring pads disposed on the top surface of the thermal ring; and
a second set of ring pads disposed on the bottom surface of the thermal ring and electrically connected to respective ones of the ring pads of the first set;
the thermal ring being disposed between the carrier layers such that the ring pads of the second set are electrically connected to respective ones of the carrier pads of the second set of one of the carrier layers, and the ring pads of the first set are electrically connected to respective ones of the carrier pads of the third set of one of the base layers.

5. The chip stack of claim 4 wherein:
the transposer layer defines opposed top and bottom surfaces; and
the third conductive pattern comprises:
a first set of transposer pads disposed on the top surface; and
a second set of transposer pads disposed on the bottom surface and electrically connected to respective ones of the transposer pads of the first set;
the carrier pads of the third set of one of the carrier layers being electrically connected to respective ones of the transposer pads of the first set.

6. The chip stack of claim 5 wherein the transposer pads of the first set, the ring pads of the first and second sets, and the carrier pads of the second and third sets are arranged in identical patterns.

7. The chip stack of claim 6 wherein:
the transposer and carrier layers each have a generally rectangular configuration defining opposed pairs of longitudinal and lateral peripheral edge segments;
the thermal ring has a generally rectangular configuration defining opposed pairs of longitudinal and lateral side sections;
the transposer pads of the first set extend along the longitudinal and lateral peripheral edge segments of the transposer layer;
the first and second sets of ring pads extend along the longitudinal and lateral side sections of the thermal ring; and
the second and third sets of carrier pads extend along the longitudinal and lateral peripheral edge segments of each of the carrier layers.

8. The chip stack of claim 6 wherein:
each of the ring pads of the first set is electrically connected to a respective one of the ring pads of the second set via a ring feed-through hole; and
each of the carrier pads of the second set is electrically connected to a respective one of the carrier pads of the third set via a carrier feed-through hole.

9. The chip stack of claim 6 wherein the integrated circuit chips each comprise a package chip including:
a body having opposed, generally planar top and bottom surfaces; and
a plurality of conductive contacts disposed on the bottom surface of the body;
the conductive contacts of each of the packaged chips being electrically connected to respective ones of the carrier pads of the first set of a respective one of the first conductive patterns.

10. The chip stack of claim 9 wherein the transposer pads of the second set, the carrier pads of the first set, and the conductive contacts are arranged in identical patterns.

11. The chip stack of claim 9 wherein the body of each of the packaged chips and the thermal ring are sized relative to each other such that the top surface of the body circumvented by the thermal ring does not protrude beyond the top surface thereof.

12. The chip stack of claim 9 wherein the packaged chips are each selected from the group consisting of:
a BGA device;
a fine pitch BGA device;
a CSP device; and
a flip chip device.

13. The chip stack of claim 9 further comprising a heat sink attached to the top surface of the body of the packaged chip disposed between the carrier layers.

14. The chip stack of claim 13 wherein the heat sink is attached to the body via an adhesive.

15. The chip stack of claim 13 wherein the heat sink is fabricated from a layer of copper.

16. The chip stack of claim 1 wherein:
the thermal ring defines a plurality of castellations; and
the flow channels are defined between each adjacent pair of the castellations.

17. The chip stack of claim 16 wherein:
the thermal ring has a generally rectangular configuration defining opposed pairs of longitudinal and lateral side sections; and
the castellations are defined within each of the longitudinal side sections of the thermal ring.

18. The chip stack of claim 16 wherein:
the thermal ring defines opposed, generally planar top and bottom surfaces, and is formed to have a ring thickness; and
the flow channels extend from the top surface of the thermal ring to a depth of approximately one-half the ring thickness.

19. The chip stack of claim 16 wherein each of the flow channels has a generally rectangular cross-sectional configuration.

20. The chip stack of claim 1 further comprising a heat sink attached to the integrated circuit chip disposed between the carrier layers.
